(19) United States
(12) Patent Application Publication
(10) Pub. No.: US 2024/0053512 A1
(43) Pub. Date: Feb. 15, 2024

(54) ANTIREFLECTION COATING, COVER STRUCTURE, AND METHOD FOR MANUFACTURING ANTIREFLECTION COATING

(71) Applicant: Honor Device Co., Ltd., Shenzhen, Guangdong (CN)

(72) Inventor: Gao YUAN, Shenzhen (CN)

(21) Appl. No.: 18/260,822

(22) PCT Filed: Apr. 24, 2022
(86) PCT No.: PCT/CN2022/088836

§ 371 Date: Jul. 10, 2023

(30) Foreign Application Priority Data
Aug. 24, 2021 (CN) 202110977681.7
Sep. 30, 2021 (CN) 202111163303.1

(51) Int. Cl. G02B 1/115

(52) U.S. Cl. CPC G02B 1/115

(57) ABSTRACT

This application discloses an antireflection coating, a cover structure, and a method for manufacturing an antireflection coating. The antireflection coating includes one or more antireflection units. The plurality of antireflection units are sequentially stacked in a first direction, and the first direction is a light-emitting direction of the antireflection coating. The one or more antireflection units include a first antireflection unit. The first antireflection unit includes a first thin film layer and a second thin film layer. The second thin film layer and the first thin film layer are sequentially stacked in the first direction, and a surface that is of the first thin film layer and that is away from the second thin film layer is a light-emitting surface of the antireflection coating.

This application claims priority to Chinese Patent Application No. 202110977681.7, filed with the China National Intellectual Property Administration on Aug. 24, 2021 and entitled “ANTIREFLECTION COATING, DISPLAY MODULE, AND TERMINAL DEVICE”, and to Chinese Patent Application No. 202111163303.1, filed with the China National Intellectual Property Administration on Sep. 30, 2021 and entitled “ANTIREFLECTION COATING, COVER STRUCTURE, AND METHOD FOR MANUFACTURING ANTIREFLECTION COATING”, which are incorporated herein by reference in their entireties.

### TECHNICAL FIELD

This application relates to the field of antireflection coating technologies, and in particular, to an antireflection coating, a cover structure, and a method for manufacturing an antireflection coating.

### BACKGROUND

An antireflection coating, also referred to as an antireflective coating, is usually used in an electronic device that has an antireflection requirement, such as a mobile phone, a tablet, a PC, a display, or a large-screen terminal, to reduce reflected light on a screen surface of the electronic device. An antireflection effect of the antireflection coating directly affects visual experience of a user in a process of using the electronic device.

However, a current antireflection coating has a poor overall antireflection effect on light, and especially has a poor antireflection effect on oblique light. As a result, a severe light reflection phenomenon exists in an electronic device to which the antireflection coating is attached, and consequently, a user cannot clearly view content on a screen. Particularly, in an electronic device having a foldable screen, a severe light reflection phenomenon further causes an obvious optical crease to the foldable screen, which greatly reduces visual experience of a user.

### SUMMARY

Embodiments of this application provide an antireflection coating, a cover structure, and a method for manufacturing an antireflection coating, to resolve a problem that a reflection phenomenon of an electronic device is severe and a problem that an obvious optical crease occurs on a foldable screen of a foldable electronic device due to a poor antireflection effect of a current antireflection coating.

To achieve the foregoing objective, the following technical solutions are used in the embodiments of this application.

According to a first aspect, an antireflection coating is provided. The antireflection coating includes one or more antireflection units. The plurality of antireflection units are sequentially stacked in a first direction. The first direction is a light-emitting direction of the antireflection coating. The one or more antireflection units include a first antireflection unit. The first antireflection unit includes a first thin film layer and a second thin film layer, and the second thin film layer and the first thin film layer are sequentially stacked in the first direction. A surface that is of the first thin film layer and that is away from the second thin film layer is a light-emitting surface of the antireflection coating. The first thin film layer is of a porous structure, the porous structure is configured to reduce a refractive index of the first thin film layer, and the refractive index of the first thin film layer is less than a refractive index of the second thin film layer.

It should be noted that, a larger quantity of antireflection units indicates a wider working band of the antireflection coating, and therefore antireflection can be performed on light of more wavelengths. Based on this, in this embodiment, one or more antireflection units are disposed to meet different requirements for a working band. Based on this, in the antireflection coating, because the surface that is of the first thin film layer and that is away from the second thin film layer is the light-emitting surface of the antireflection coating, the first thin film layer is a part or all of a surface thin film layer of the antireflection coating. Based on this, the first thin film layer in the first antireflection unit is set to the porous structure, to reduce a refractive index of the surface thin film layer at which the light-emitting surface of the antireflection coating is located, thereby achieving an objective of antireflection. Specifically, because there are a large quantity of hollow holes in the porous structure, and a medium in the hole is air, the antireflection coating as a whole may be considered as a structure formed by mixing air with a material forming the antireflection coating. A refractive index of air is a medium with a minimum refractive index other than air, and a material with a smaller refractive index cannot be found. Therefore, existence of air inevitably reduces the refractive index of the first thin film layer. In other words, in this embodiment, the refractive index of the first thin film layer may be reduced by designing the porous structure, to reduce the refractive index of the surface thin film layer. In addition, a proportion of air may be controlled by adjusting a quantity of holes, to control a reduction range of the refractive index of the first thin film layer, so that the refractive index of the first thin film layer is less than the refractive index of the second thin film layer, and is closer to a square root of the refractive index of air and a refractive index of a secondary thin film layer (a thin film layer in contact with the surface thin film layer), thereby improving an antireflection effect of the antireflection coating.

It should be understood that, after an antireflection effect of the antireflection coating is improved, an antireflection effect of the antireflection coating at each angle is improved. In other words, in this example, in addition to improving an antireflection effect on vertical light, an antireflection effect on oblique light can also be improved, so that a reflection phenomenon of oblique light can be effectively suppressed. It should be understood that, after oblique light generated in a daily use process of a screen of an electronic device is effectively suppressed, a light reflection phenomenon of the screen is weakened, so that a user can more clearly identify displayed content on a screen of a mobile phone, thereby greatly improving visual experience of the user. In addition, after oblique light in a bending region of a foldable electronic device is effectively suppressed, a reflection phenomenon in the bending region is weakened, so that an optical crease in the bending region is weakened or even disappears, thereby greatly improving visual experience of the user.

In some embodiments, density of a hole that is of the first thin film layer and that is close to the light-emitting surface of the antireflection coating is greater than density of a hole that is of the first thin film layer and that is away from the light-emitting surface of the antireflection coating. In this way, in this example, holes on an upper side (a side close to the light-emitting surface of the antireflection coating) of the first thin film layer are denser, and holes on a lower side (the side close to the light-emitting surface of the antireflection coating) of the first thin film layer are sparser.

When large-angle oblique light is incident onto the antireflection coating and encounters a hole at the first thin film layer, the oblique light is reflected or refracted on a hole wall, and then is reflected or refracted again when encountering another hole, until some light is transmitted from the light-emitting surface (upstream) of the antireflection coating, and some light is transmitted to the lower second thin film layer (downstream). It can be learned that light entering the first thin film layer is usually refracted and reflected a plurality of times, and then goes upstream or downstream. It should be understood that, after light is reflected a plurality of times, a reflectivity of the light is reduced (the reflectivity is less than 1%). Therefore, a reflectivity of light that is transmitted from the antireflection coating due to the porous structure can be ignored. In addition, there is only an extremely small amount of upstream light, and most light goes downstream. A reason lies in the following: The holes on the upper side of the first thin film layer are denser, so that the upstream light is more likely to encounter the holes and be reflected to go downstream. However, the downstream light is more likely to pass through a region between the holes, to continue to go downstream in an original direction. Based on this, because an amount of upstream light caused by the porous structure is extremely small, it is further verified that the reflectivity of the light that is transmitted from the antireflection coating due to the porous structure can be ignored.

In addition, an incident angle (relative to the second thin film layer) of the downstream light becomes smaller. A reason lies in the following: If the downstream light is large-angle oblique light, in a downstream process, the downstream light is easily reflected or refracted by the hole to change a transmission direction or even go upstream, instead of passing through the region between the holes to continue to go downstream in the original direction. Because the porous structure finally enables most light to go downstream, if the large-angle light needs to go downstream, an incident angle of the light is inevitably integrated by the holes in the porous structure in a refraction and reflection process, until the incident angle of the light is small and the light can be irradiated to the second thin film layer. When the incident angle of the downstream light decreases, an optical path length n₂*d₂/cos θ through which the downlink light passes at the second thin film layer decreases, where d₂ is a geometric thickness of the second thin film layer, n₂ is the refractive index of the second thin film layer, λ₀ is a wavelength of light in the air, and k is a natural number. Based on this, when the second thin film layer is also a part of the surface thin film layer, an optical thickness n₂*d₂/cos θ of the second thin film layer decreases, so that an optical thickness of the surface thin film layer is closer to (2k+1)λ₀/4, thereby helping improve an antireflection effect of the antireflection coating.

In some embodiments of this application, a geometric thickness of the first thin film layer meets the following equation: n₁*d₁=(2k+1)λ₀/4, where di is the geometric thickness of the first thin film layer, n₁ is the refractive index of the first thin film layer, λ₀ is a wavelength of light in the air, and k is a natural number. It should be noted that, when the first antireflection unit includes only the first thin film layer and the second thin film layer, and the refractive index of the second thin film layer is greater than the refractive index of the first thin film layer, the first thin film layer forms a low refraction layer of the first antireflection unit, and the second thin film layer forms a high refraction layer of the first antireflection unit. In this case, the first thin film layer is the surface thin film layer of the antireflection coating, and the second thin film layer forms the secondary thin film layer of the antireflection coating. When a geometric thickness of the surface thin film layer—the first thin film layer meets n₁*d₁=(2k+1)λ₀/4, if light whose wavelength is λ₀ is incident onto the first thin film layer, an optical path difference between two columns of reflected light reflected through an upper surface and a lower surface of the first thin film layer is (2k+1)λ₀/2. In this case, a phase difference between the two columns of reflected light is (2k+1)π, so that interference destruction can be implemented to a largest extent, to help improve antireflection effects of the antireflection coating on incident light at different angles.

Further, the plurality of antireflection units include a second antireflection unit, and the second antireflection unit is stacked on a surface that is of the second thin film layer and that is away from the first thin film layer. The second antireflection unit includes a third thin film layer and a fourth thin film layer. The fourth thin film layer and the third thin film layer are sequentially stacked in the first direction, a refractive index of the fourth thin film layer is greater than a refractive index of the third thin film layer, and the refractive index of the third thin film layer is less than the refractive index of the second thin film layer. In this way, the antireflection coating includes two antireflection units, and refractive indexes of the first thin film layer, the second thin film layer, the third thin film layer, and the fourth thin film layer are arranged by alternating between a lower rank and a higher rank, so that a working band of the antireflection coating can be widened, so as perform antireflection on light of more wavelengths.

In some other embodiments of this application, the first antireflection unit further includes a third thin film layer. The second thin film layer is stacked on a surface of the third thin film layer, and a refractive index of the third thin film layer is greater than the refractive index of the second thin film layer.

It should be noted that, when the first antireflection unit includes the first thin film layer, the second thin film layer, and the third thin film layer, and the refractive index of the third three film layers>the refractive index of the second thin film layer>the refractive index of the first thin film layer, the first thin film layer and the second thin film layer are multiplexed as a low refraction layer of the first antireflection unit, and the third thin film layer forms a high refraction layer of the first antireflection unit. In other words, the first thin film layer and the second thin film layer jointly form the surface thin film layer of the antireflection coating, and the third thin film layer jointly forms the secondary thin film layer of the antireflection coating. It can be learned that a decrease in the refractive index of the first thin film layer inevitably reduces a refractive index of the low refraction layer of the first antireflection unit, that is, the refractive index of the surface thin film layer of the antireflection coating, so that the refractive index of the surface thin film layer is closer to a square root of the refractive index of the air and the refractive index of the secondary film layer, thereby helping improve antireflection effects of the antireflection coating on incident light at different angles. Further, a geometric thickness of the first thin film layer meets the following equation: n₁*d₁+n₂*d₂=(2k+1)λ₀/4, where d₁ is the geometric thickness of the first thin film layer, n₁ is the refractive index of the first thin film layer, d₂ is a geometric thickness of the second thin film layer, n₂ is the refractive index of the second thin film layer, λ₀ is a wavelength of light in the air, and k is a natural number.

In this embodiment, when an optical thickness of the surface thin film layer meets that n₁*d₁+n₂*d₂=(2k+1)λ₀/4, if light whose wavelength is λ₀ is incident onto the surface thin film layer, an optical path difference between two columns of reflected light reflected by an upper surface of the first thin film layer (a surface away from the second thin film layer) and a lower surface of the second thin film layer (the surface away from the second thin film layer) is (2k+1)λ₀/2. In this case, a phase difference between the two columns of reflected light is (2k+1)π, so that interference destruction can be implemented to a largest extent, to help improve antireflection effects of the antireflection coating on incident light at different angles.

Further, the plurality of antireflection units include a second antireflection unit, and the second antireflection unit is stacked on a surface that is of the third thin film layer and that is away from the second thin film layer. The second antireflection unit includes a fourth thin film layer and a fifth thin film layer. The fifth thin film layer and the fourth thin film layer are sequentially stacked in the first direction, a refractive index of the fifth thin film layer is greater than a refractive index of the fourth thin film layer, and the refractive index of the fourth thin film layer is less than the refractive index of the third thin film layer. In this way, the antireflection coating includes two antireflection units, and refractive indexes of the second thin film layer, the third thin film layer, the fourth thin film layer, and the fifth thin film layer are arranged by alternating between a lower rank and a higher rank, so that a working band of the antireflection coating can be widened, so as to perform antireflection on light of more wavelengths.

In some embodiments, the first thin film layer is made of a transparent material. In this way, light can be transmitted to the second thin film layer through the transparent material, to reduce a reflectivity of the light.

In some embodiments, the antireflection coating is applied to a foldable electronic device. A bending region of the foldable electronic device is slightly deformed after being used for a long time. As a result, light becomes oblique light, and a light reflection phenomenon occurs in the bending region relative to another region, a strong contrast occurs, and an optical crease is formed. When the antireflection coating is applied to the foldable electronic device, the light reflection phenomenon of the oblique light in the bending region can be reduced, to mitigate the optical crease, thereby improving visual experience of a user.

According to a second aspect, a cover structure is provided. The cover structure includes a cover and the antireflection coating according to any one of the embodiments of first aspect. The antireflection coating and the cover are stacked, and a second surface of the antireflection coating is further away from the cover.

In some embodiments, the cover structure further includes a buffer layer, and the buffer layer is made of a high-surface-energy material. The buffer layer is stacked between the cover and the antireflection coating, and includes a first surface and a second surface that are disposed opposite to each other. The first surface of the buffer layer is in contact with the second surface of the antireflection coating, and the second surface of the buffer layer is in contact with a cover surface of the cover. In this embodiment, the buffer layer with high surface energy is processed between a hardening layer—the cover and the antireflection coating, so that bonding force between the antireflection coating and the cover can be enhanced, and the cover structure has better wear-resistance performance.

According to a third aspect, an antireflection coating is provided. The antireflection coating is of a porous structure, and the porous structure is configured to reduce a refractive index of the antireflection coating.

In some embodiments, density of a hole that is of the antireflection coating and that is close to a light-emitting surface of the antireflection coating is greater than density of a hole that is of the antireflection coating and that is away from the light-emitting surface of the antireflection coating.

In some embodiments, a geometric thickness of the antireflection coating is 200 nm or less.

Further, the gemetric thickness of the antireflection coating meets the following equation: n₁*d₁=(2k+1)λ₀/4, where d₁ is the geometric thickness of the antireflection coating, n₁ is the refractive index of the antireflection coating, λ₀ is a wavelength of light in the air, and k is a natural number.

In some embodiments, the antireflection coating is made of a transparent material.

In some embodiments, the antireflection coating is applied to a foldable electronic device.

According to a fourth aspect, a cover structure is provided. The cover structure includes a cover and the antireflection coating according to any one of the embodiments of the third aspect. The antireflection coating and the cover are stacked, and a refractive index of the antireflection coating is less than a refractive index of the cover.

According to a fifth aspect, an electronic device is provided. The electronic device includes a display panel and the cover structure according to the second aspect or the fourth aspect. The cover structure and the display panel are stacked, and the cover is closer to the display panel.

According to a sixth aspect, a method for manufacturing an antireflection coating is further provided, and the method is used to manufacture the antireflection coating according to the first aspect. The method for manufacturing an antireflection coating includes:

forming a second thin film layer; sputtering a surface of the second thin film layer to form a first to-be-processed thin film layer, where the first to-be-processed thin film layer includes at least a first acid-intolerant substance and a first acid-tolerant substance; corroding the first to-be-processed thin film layer by using an acid solution, to form a first thin film layer of a porous structure, where a hole in the porous structure is formed after the acid solution reacts with the first acid-intolerant substance, the porous structure is configured to reduce a refractive index of the first thin film layer, and the refractive index of the first thin film layer is less than a refractive index of the second thin film layer; and obtaining an antireflection coating, where the antireflection coating has a first surface and a second surface that are disposed opposite to each other, and a surface that is of the first thin film layer and that is away from the second thin film layer is a first surface of the antireflection coating.

In the manufacturing method, because the first to-be-processed thin film layer is formed by using a sputtering process, a basic unit of the first acid-intolerant substance that forms the first to-be-processed thin film layer is a molecular-level substance or even an ion-level substance. Therefore, denser and more uniform holes can be formed after the first acid-intolerant substance reacts with the acid solution, so that surface roughness of the formed antireflection coating is small, thereby improving wear-resistance performance of the antireflection coating. It should be understood that, when a cover structure is applied to a screen surface of an electronic device such as a mobile phone, a user performs sliding on the cover structure for a long time, and a structure of an antireflection coating with poor wear-resistance performance is changed in a process of performing sliding by the user. Consequently, an antireflection effect of the antireflection coating is greatly reduced. On the contrary, in this embodiment, because the antireflection coating has high wear-resistance performance, a structure of the antireflection coating is not easily changed in the process of performing sliding by the user, which helps ensure an antireflection effect of the antireflection coating, thereby improving reliability of the electronic device.

According to a seventh aspect, a method for manufacturing an antireflection coating is further provided, and the method is used to manufacture the antireflection coating according to the third aspect. The method for manufacturing an antireflection coating includes: forming a second to-be-processed thin film layer through sputtering, where the second to-be-processed thin film layer includes at least a second acid-intolerant substance and a second acid-tolerant substance; corroding the second to-be-processed thin film layer by using an acid solution, to form an antireflection coating of a porous structure, where a hole in the porous structure is formed after the acid solution reacts with the second acid-intolerant substance, and the porous structure is configured to reduce a refractive index of the antireflection coating; and obtaining the antireflection coating.

For technical effects brought by any implementation of the second aspect to the fifth aspect, refer to the technical effects brought by different implementations of the first aspect. For technical effects brought by any implementation of the seventh aspect, refer to the technical effects brought by different implementations of the sixth aspect. Details are not described herein again.

### BRIEF DESCRIPTION OF DRAWINGS

FIG. 1 is a schematic diagram of a waveform of interference destruction of light according to an embodiment of this application;

FIG. 2 is a schematic diagram of light effects of an antireflection coating on incident light at different angles in a possible implementation;

FIG. 3A is a schematic diagram of a structure of an electronic device according to some embodiments of this application;

FIG. 3B is a schematic diagram of a structure of a cover structure according to some embodiments of this application;

FIG. 4A is a schematic diagram of a structure of an electronic device according to some other embodiments of this application;

FIG. 4B is a schematic diagram of a structure of an electronic device according to some other embodiments of this application;

FIG. 5A is a schematic diagram of a structure of a cover structure according to some other embodiments of this application;

FIG. 5B is a schematic diagram of a structure of an antireflection coating of a porous structure according to some embodiments of this application;

FIG. 6A is a flowchart of a method for manufacturing a cover structure shown in FIG. 5A according to some embodiments of this application;

FIG. 6B is a flowchart of a method for manufacturing an antireflection coating shown in FIG. 5A according to some embodiments of this application;

FIG. 7 is a schematic diagram of a structure of a cover structure according to some other embodiments of this application;

FIG. 8 is a diagram of comparison between reflectivities, for incident light, of antireflection coatings having thin film layers of different structures according to some embodiments of this application;

FIG. 9A is a flowchart of a method for manufacturing a cover structure shown in FIG. 7 according to some other embodiments of this application;

FIG. 9B is a flowchart of a method for manufacturing an antireflection coating shown in FIG. 7 according to some other embodiments of this application;

FIG. 10 is a schematic diagram of a structure of a cover structure according to some other embodiments of this application;

FIG. 11A is a flowchart of a method for manufacturing a cover structure shown in FIG. 10 according to some other embodiments of this application; and

FIG. 11B is a flowchart of a method for manufacturing an antireflection coating shown in FIG. 10 according to some other embodiments of this application.

### DESCRIPTION OF EMBODIMENTS

In embodiments of this application, the terms “first” and “second” are merely used for the purpose of description, and cannot be construed as an indication or implication of relative importance or an implicit indication of a quantity of indicated technical features. Therefore, a feature defined by “first” or “second” may explicitly or implicitly include one or more such features.

In this application, the orientation terms such as “top” and “bottom” are defined relative to the orientations in which the components are schematically placed in the accompanying drawings. It should be understood that these directional terms are relative concepts, are used for relative description and clarification, and may be correspondingly changed based on changes in the orientations in which the components are placed in the accompanying drawings.

To better understand the solutions in this application, the following describes terms in embodiments of this application.

(1) Light Interference

Light interference is an optical phenomenon in which two columns of optical waves that have a same frequency, a constant phase difference, and a same vibration direction are mutually superimposed when meeting in a transmission process, to generate interference construction (strengthening) and/or interference destruction (weakening).

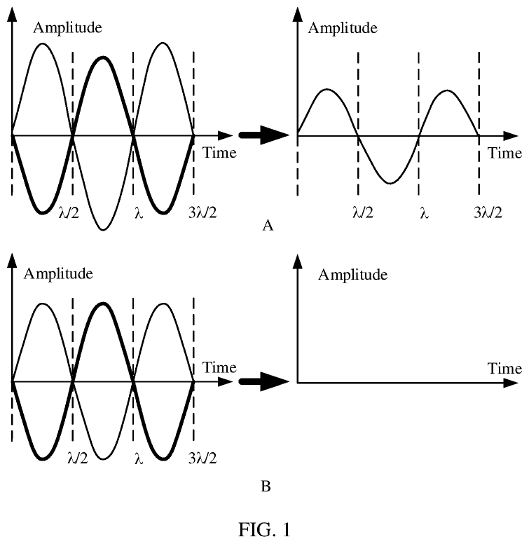

As shown in A in FIG. 1, when a phase difference between two columns of optical waves that have different amplitudes and that are represented by using a thick line and a thin line is exactly (2k+1)π, that is, a distance difference between the two columns of optical waves is (2k+1)λ₀/2, the amplitudes are partially cancelled, where λ₀ is a wavelength of the optical wave in the air, and k is a natural number.

As shown in B in FIG. 1, when a phase difference between two columns of optical waves that have a same amplitude and that are represented by using a thick line and a thin line is exactly (2k+1)π, that is, a distance difference between the two columns of optical waves is (2k+1)λ₀/2, the amplitudes are completely cancelled, where k is a natural number.

Through comparison between A in FIG. 1 and B in FIG. 1, it can be found that to implement 100% cancellation for two columns of optical waves, a phase difference between the two columns of optical waves should be exactly (2k+1)π, that is, a distance difference between the two columns of optical waves should be (2k+1)λ₀/2, and amplitudes of the two columns of optical waves should be the same.

(2) Geometric Thickness and Optical Thickness of a Thin Film

The geometric thickness is a physical thickness or an actual thickness of a film layer of the thin film, and a product of the geometric thickness and a refractive index of the film layer of the thin film is referred to as the optical thickness.

For example, assuming that the geometric thickness of the thin film is d and a refractive index of the thin film is n, the optical thickness of the thin film is n*d.

(3) Optical Path Length and Optical Path Difference

The optical path length is a product of a geometric distance of light propagation and a refractive index of a medium.

The optical path difference is a difference between optical path lengths of two beams of light.

(4) A front Surface of a Display Panel is a Surface on Which the Display Panel Outputs Displayed Content.

(5) Surface Thin Film Layer

The surface thin film layer is a thin film layer that is of an antireflection coating and that is farthest away from a cover. It should be noted that, when vertically incident light (which is subsequently referred to as vertical light) whose wavelength is λ₀ is incident onto the surface thin film layer, a condition for the surface thin film layer to have a zero reflection on the vertical light whose wavelength is λ₀ is as follows:

an optical thickness of the surface thin film layer is n₁*d=(2k+1)λ₀/4, and a refractive index m of the surface thin film layer is equal to a square root of a product of refractive indexes of media on two sides, that is, \sqrt{n₀*n₂}, where n₁ is separately the refractive index of the surface thin film layer, n₀ and n₂ are respectively the refractive indexes of the media on the two sides of the surface thin film layer, λ₀ is a wavelength of light in the air, k is a natural number, and d is a geometric thickness of the surface thin film layer.

It should be noted a wavelength λ of light in a medium and a wavelength λ₀ of light in the air have the following relationship: λ₀=λ/n₁. Based on this, when the optical thickness of the surface thin film layer is n₁*d=(2k+1)λ₀/4, it indicates that the geometric thickness of the surface thin film layer is d=(2k+1)λ/4=(2k+1)λ₀/4n₁.

It should be noted that, when n₁*d=(2k+1)λ₀/4, a phase difference between two columns of reflected light reflected by an upper surface and a lower surface of the surface thin film layer is exactly (2k+1)π; and when n₁=\sqrt{n₀*n₂}, amplitudes of the two columns of reflected light reflected by the upper surface and the lower surface of the surface thin film layer are the same. Based on related content of the technical term (1), it can be learned that, when a phase difference between two columns of waves is (2k+1)π (and amplitudes of the two columns of waves are the same, the amplitudes are completely cancelled. Therefore, when n₁*d=(2k+1)λ₀/4 or d=(2k+1)λ₀/4n₁, and n₁=\sqrt{n₀*n₂}, the surface thin film layer has a zero reflection effect on vertically incident light (which is subsequently referred to as vertical light) whose wavelength is λ₀.

It should be understood that, when n₁=\sqrt{n₀*n₂}, n₁ is between n₀ and n₂. Therefore, to enable n₁=\sqrt{n₀*n₂}, during material selection, a material should be selected from materials whose refractive indexes are between n₀ and n₂. However, although a material whose refractive index is between n₀ and n₂ can be found in an actual implementation process, the material may not exactly meet n₁=\sqrt{n₀*n₂}. Therefore, during material selection, the refractive index n₁ of the material should be as close as possible to \sqrt{n₀*n₂} while being between n₀ and n₂ as far as possible.

(6) High Refraction Layer and Low Refraction Layer

The high refraction layer and the low refraction layer in the embodiments of this application are relative concepts. A refractive index of the low refraction layer is less than a refractive index of the high refraction layer.

(7) Light-Emitting Surface of an Antireflection Coating

The light-emitting surface of the antireflection coating is a surface that is of the antireflection coating and that is away from an optical component (for example, a cover in the embodiments of this application) when the antireflection coating is stacked on an optical surface of the optical component and is used.

A surface opposite to the light-emitting surface of the antireflection coating is a light-incident surface of the antireflection coating.

(8) Light-Emitting Direction of an Antireflection Coating

The light-emitting direction of the antireflection coating is a direction that is perpendicular to a light-emitting surface of the antireflection coating and that extends from a light-incident surface of the antireflection coating to the light-emitting surface of the antireflection coating.

An antireflection coating, also referred to as an antireflective coating, is usually used in an electronic device that has an antireflection requirement, such as a mobile phone, a tablet, a PC, a display, or a large-screen terminal, to reduce reflected light on a screen surface of the electronic device. An antireflection effect of the antireflection coating directly affects visual experience of a user in a process of using the electronic device. Currently, an antireflection coating applied to the electronic device has a good antireflection effect on only vertical light, and has a poor antireflection effect on large-angle oblique light.

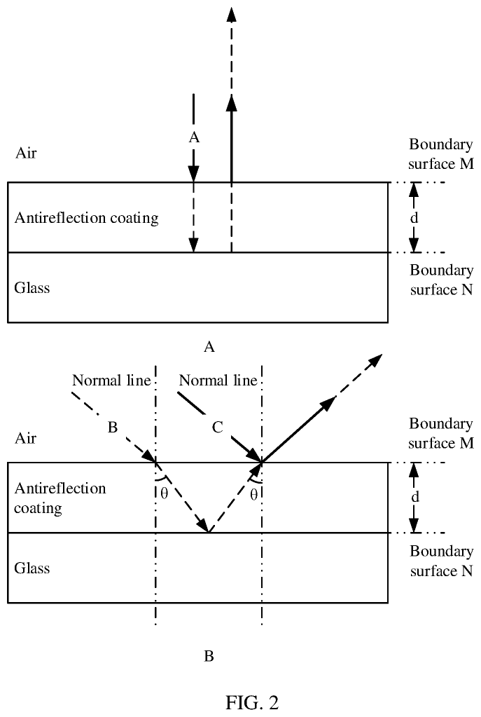

Referring to FIG. 2, a single-layer antireflection coating is used as an example. FIG. 2 is a schematic diagram of light effects of an antireflection coating on incident light at different angles. A geometric thickness of the antireflection coating is d, a refractive index of the antireflection coating is n, a boundary surface M is a boundary surface between air and the antireflection coating, and a boundary surface N is a boundary surface between the antireflection coating and glass (a screen and a protection layer that are of an electronic device). To avoid affecting display due to overlapping between reflected light and incident light, the reflected light and the incident light are displayed separately in the figure.

In FIG. 2, A is a schematic diagram of a light effect of an antireflection coating on vertical light. As shown in A in FIG. 2, vertical light A whose wavelength is λ₀ is divided into two pieces of light after being incident onto the antireflection coating. One piece of light is reflected at the boundary surface M (shown by a solid line in the figure). The other piece of light is transmitted to the antireflection coating and is reflected at the boundary surface N, and then is transmitted from the antireflection coating at the boundary surface M (shown by a dashed line in the figure). When an optical thickness of the antireflection coating is n*d=(2k+1)λ₀/4, an optical path difference L1 between the two pieces of light is 2n*d=(2k+1)λ₀/2, and the antireflection coating may have a zero reflection effect on the vertical light A whose wavelength is λ₀.

However, an antireflection coating with a same optical thickness has a poorer antireflection effect on oblique light of a same wavelength than the vertical light. B in FIG. 2 is a schematic diagram of a light effect of an antireflection coating on oblique light. Oblique light B whose wavelength is λ₀ is transmitted to the antireflection coating after being incident onto the antireflection coating and is reflected at the boundary surface N, and then is transmitted from the antireflection coating at the boundary surface M (a dashed line shows a propagation path of the oblique light B). Oblique light C whose wavelength is λ₀ is reflected at the boundary surface M after being incident onto the antireflection coating (a solid line shows a propagation path of the oblique light C). Apparently, an optical path difference L2 between the light B and the light C is 2n*d/cos θ, where θ is a refraction angle of light incident onto the antireflection coating from air. When the optical thickness n*d is (2k+1)λ₀/4, the optical path difference L2 is (2k+1)λ₀/2cos θ, and is no longer (2k+1)λ₀/2. Interference between reflected light of the oblique light B at the boundary surface N and reflected light of the oblique light C at the boundary surface M is constructed in some regions, and is destructed in some regions, so that an antireflection effect on oblique light is poorer than that on vertical light. As an incident angle of the oblique light increases, the refraction angle θ increases accordingly, and the optical path difference L2 increases, so that phases of the two columns of reflected light are increasingly close to kπ, and a reflectivity is increasingly large. It should be noted that, when the incident angle of the oblique light is small, an increase in a reflectivity can be ignored. However, when the incident angle is large, especially when the incident angle enables the phases of the two columns of reflected light to be kπ, the reflectivity is excessively high, and a severe light reflection phenomenon is generated.

It is found through study by the inventor that oblique light usually occurs in the following two scenarios.

First, in a normal use process of an electronic device, a location of a light source relative to the electronic device is uncertain. Therefore, light incident onto a screen of the electronic device may be oblique light.

Second, after an electronic device with a foldable screen is used for a period of time, a bending region of the foldable screen is slightly deformed, and therefore light in the bending region may be oblique light.

When the antireflection coating cannot effectively suppress a reflection phenomenon of oblique light, a light reflection phenomenon occurs on the screen of the electronic device. In the first scenario, due to the light reflection phenomenon, a user cannot clearly view content displayed on a screen of a mobile phone. In addition, in the second scenario, the light reflection phenomenon causes an obvious optical crease in the bending region. It can be learned that in either case, visual experience of a user is greatly reduced.

To resolve the foregoing problem that because the antireflection coating cannot suppress reflection of oblique light of the electronic device, severe reflection occurs on the electronic device, and visual experience of a user cannot be ensured, in the embodiments of this application, a new surface thin film layer is formed by stacking a thin film layer of a porous structure on a surface thin film layer of an existing antireflection coating (the thin film layer of the porous structure and the original surface thin film layer are multiplexed to form the new surface thin film layer), or the surface thin film layer of the existing antireflection coating is replaced with a thin film layer of a porous structure, to improve antireflection effects of the antireflection coating at different angles. The following describes in detail the embodiments of this application.

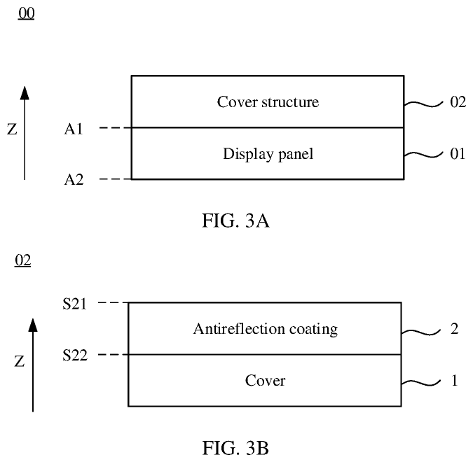

An embodiment of this application provides an electronic device. The electronic device may include electronic products having an antireflection requirement, such as a mobile phone (mobile phone), a tablet computer (pad), a television, a smart wearable product (for example, a smartwatch or a smart band), a virtual reality (virtual reality, VR) terminal device, and an augmented reality (augmented reality, AR) terminal device. A specific form of the electronic device is not specially limited in this embodiment of this application. For ease of description, an example in which the electronic device is a mobile phone shown in FIG. 3A is used below for description.

Referring to FIG. 3A, the electronic device 00 may include a display panel 01. The display cover 01 has a first cover surface A1 and a second cover surface A2 that are disposed opposite to each other. The first cover surface A1 of the display cover 01 is a front surface A1 of the display cover 01, and is configured to output displayed content. For ease of the following description, a Z direction shown in the figure is perpendicular to the cover surface A1 of the display cover 01, and extends from the second cover surface A2 of the display cover 01 to the first cover surface A1 of the display cover 01. It can be learned that the Z direction is a light-emitting direction of the electronic device 00, that is, an emitting direction of light perpendicular to the front surface of the display cover 01.

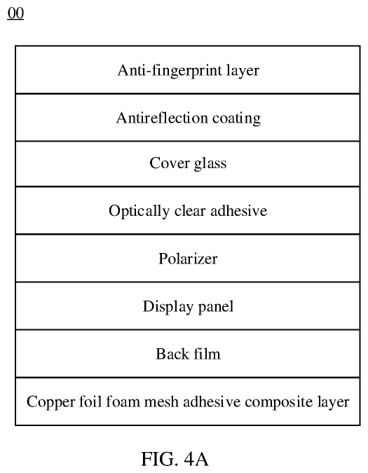

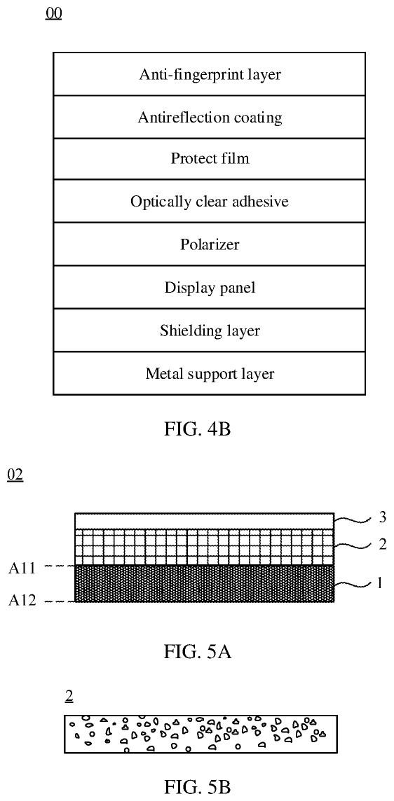

To protect the display cover 01 from being damaged, the electronic device 00 further includes a cover structure 02. The display cover 01 and the cover structure 02 are sequentially stacked in the Z direction, that is, the cover structure 02 is stacked on the front surface A1 of the display cover 01, to protect the display panel 01 from being damaged. It should be understood that the display panel 01 and the cover structure 02 are minimum composition units of the electronic device 00. In a specific implementation process, the electronic device 00 shown in FIG. 3A may include more components than those shown in the figure. For example, refer to electronic devices 00 shown in FIG. 4A and FIG. 4B. The electronic devices 00 shown in FIG. 4A and FIG. 4B are described in detail in a subsequent embodiment. Details are not described herein.

FIG. 3B is a schematic diagram of a structure of a cover structure according to some embodiments of this application. The cover structure 02 may include a cover 1 and an antireflection coating 2. The antireflection coating 2 has a first surface S21 and a second surface S22 that are disposed opposite to each other. The first surface S21 of the antireflection coating 2 is a light-emitting surface S21 of the antireflection coating 2, and the light-emitting surface S21 of the antireflection coating 2 is closer to the cover 1. For ease of the following description, a Z direction shown in the figure is perpendicular to the light-emitting surface S21 of the antireflection coating 2 and extends from the second surface S22 of the antireflection coating 2 to the first surface S21 of the antireflection coating 2, that is, the Z direction is a light-emitting direction of the light-emitting surface of the antireflection coating 2, and is also a direction perpendicular to the cover 1 and extending from the cover 1 to the antireflection coating 2. The cover 1 and the antireflection coating 2 are sequentially stacked in the Z direction.

It should be understood that the cover structure 2 shown in FIG. 3B may be applied to the electronic device 00 shown in FIG. 3A. When the cover structure 2 is applied to the electronic device 00 shown in FIG. 3A, the Z direction in FIG. 3B and the Z direction in FIG. 3B are a same direction. Based on this, in the cover structure 02 on the front surface of the display panel 01, the cover 1 is in contact with the display panel 01, and is configured to protect the display panel 01 from being damaged; and the antireflection coating 2 covers a surface that is of the cover 1 and that is away from the display panel 01, and is configured to suppress reflected light on the front surface of the display panel 01. It should be understood that, when specific types of the electronic device 00 to which the cover structure 02 is applied are different, specific implementation of the cover 1 is different. With reference to FIG. 4A and FIG. 4B, the following describes specific implementation of the electronic device 00 and specific implementation of the cover 1 by using an example.

For example, an example in which the electronic device 00 is a single-screen mobile phone shown in FIG. 4A is used for description. As shown in FIG. 4A, the electronic device 00 may include a copper foil foam mesh adhesive composite layer SCF, a back film (back film, BF), a display panel, a polarizer (polarizer, POL), an optically clear adhesive (optically clea adhesive, OCA), cover glass (cover glass, CG), an antireflection (antireflection, AR) coating, and an anti-fingerprint (anti-fingerprint, AF) layer that are sequentially stacked. The SCF may be configured to perform functions of shielding interference from an electrical signal of a mainboard (not shown in the figure) of the electronic device 00 to the display panel, shielding light, performing buffering, and the like. The BF may be configured to support the display panel. The display panel is configured to output displayed content. The POL is configured to form polarized light. The OCA is configured to bond the POL and the CG. The AR is configured to suppress reflected light on the front surface of the display panel. The AF layer is configured to form a hydrophobic and oleophobic layer on a screen surface of the electronic device 00. It should be understood that components in the electronic device 00 may include more or fewer components than those shown in the figure. FIG. 4A should not be understood as a special limitation on a form of the electronic device 00.

In another example, an example in which the electronic device 00 is a foldable-screen mobile phone shown in FIG. 4B is used for description. As shown in FIG. 4B, the electronic device 00 may include a metal support layer, a shielding layer (shielding layer, SL), a BF, a display panel, a POL, an OCA, a protect film (protect film, PF), an antireflection (antireflection, AR) coating, and an anti-fingerprint (anti-fingerprint, AF) layer that are sequentially stacked. A feature and a function of the PF are similar to those of the CG, except that the PF supports folding. Similarly, for other structures, refer to explanation of related content in FIG. 4A. Details are not described herein again. In addition, it should be noted that, the layers of structures shown in FIG. 4A and FIG. 4B may be implemented by using other structures that have similar functions. FIG. 4A and FIG. 4B are merely examples, and should not be understood as a limitation on a form of the electronic device 00. It should be understood that components in the electronic device 00 may include more or fewer components than those shown in the figure. FIG. 4B should not be understood as a special limitation on a form of the electronic device 00.

It can be understood that, when the cover structure 02 shown in FIG. 3B is applied to the electronic device 00 shown in FIG. 4A, the cover 1 may be the CG shown in FIG. 4A, that is, the CG and the antireflection coating jointly form the cover structure 02 in FIG. 3B; and when the cover structure 02 shown in FIG. 3B is applied to the electronic device 00 shown in FIG. 4B, the cover 1 may be the PF shown in FIG. 4B, and the PF and the antireflection coating jointly form the cover structure 02 in FIG. 3B. In another embodiment, the AF layers shown in FIG. 4A and FIG. 4B may also be considered as components of the cover structure 02 in FIG. 3B. In addition, the cover structure 02 may further include another structure, for example, a buffer layer 4 in the following Example 2 and Example 3. This is not specifically limited in this embodiment of this application.

After a relative relationship between the cover structure 02 and the electronic device 00 is determined, the cover structure 02 provided in this embodiment of this application is described below in detail by using different examples. The cover structure 02 provided in the following examples may be applied to the electronic devices 00 shown in FIG. 3A, FIG. 4A, and FIG. 4B. In addition, this embodiment of this application further provides an antireflection coating. It should be understood that serving as a component of the cover structure 02, the antireflection coating 2 is also described in a process of describing the cover structure 02. Therefore, for the antireflection coating provided in this embodiment of this application, refer to specific implementation of the antireflection coating 2 in the following examples. The provided antireflection coating is not separately described in this embodiment of this application.

### Example 1

As shown in FIG. 5A, the cover structure 02 may include a cover 1 and an antireflection coating 2 of a single-layer structure that are sequentially stacked in a Z direction. For specific description of the Z direction, refer to related description in FIG. 3B. Details are not described herein again.

The cover 1 has a first cover surface A11 and a second cover surface A12 that are disposed opposite to each other. The second cover surface A12 of the cover 1 is configured to connect to the front surface of the display panel 01, so that the cover 1 is stacked on the front surface of the display panel 01 to protect the display panel 01. The first cover surface A11 of the cover 1 is configured to enable the antireflection coating 2 to be stacked. For example, the cover 1 may be the CG in FIG. 4A, or may be the PF in FIG. 4B. The antireflection coating 2 is stacked on one side of the first cover surface A11 of the cover 1. In addition, to reduce tension on a screen surface of an electronic device, so that the screen surface has a strong hydrophobic capability, anti-oil capability, and anti-fingerprint capability, the cover structure 02 may further include an AF layer 3. The AF layer 3 is stacked on an upper part of the antireflection coating 2 (that is, a surface that is of the antireflection coating 2 and that is away from the cover 1). It should be understood that, in another embodiment, the cover structure 02 may not include the AF layer 3. This is not specifically limited in this embodiment of this application.

Because the antireflection coating 2 is of a single-layer structure, the antireflection coating 2 is also a surface thin film layer. In this example, media on two sides of the antireflection coating 2 are respectively the cover 1 and air (the AF layer 3 can be ignored). It is assumed that a refractive index of the air is n₀, a refractive index of the antireflection coating 2 is n₁, and a refractive index of the cover 1 is n₂. To enable the surface thin film layer to meet a zero reflection condition (the refractive index of the surface thin film layer is close to or even equal to \sqrt{n₀*n₂}) as far as possible, the antireflection coating 2 is a low refraction layer, and the cover 1 is a high refraction layer. Generally, the refractive index no of the air is 1. For example, the cover 1 is glass, and the refractive index n₂ of the glass is usually 1.5. In this case, during material selection, the refractive index n₁ of the antireflection coating 2 needs to be 1∞4.5, and is close to or equal to \sqrt{1.5*1}=1.23.

Among common light film materials on the market, materials that can be selected include silicon dioxide (whose refractive index is 1.46), barium fluoride (whose refractive index is 1.40), aluminum fluoride (whose refractive index is 1.35), and magnesium fluoride (whose refractive index is 1.38). It is difficult to find a material whose refractive index is less than that of magnesium fluoride, and few materials can be selected. Therefore, in a related technology, the antireflection coating 2 is usually made of aluminum fluoride and magnesium fluoride. However, even if the antireflection coating 2 is made of aluminum fluoride and magnesium fluoride, the refractive index of the antireflection coating 2 is still relatively different from 1.23, and a residual reflectivity is not ideal. It can be learned that it is difficult to make the refractive index n₁ of the antireflection coating 2 equal to or close to 1.23 by simply selecting a material, and it is difficult to implement zero reflection. Based on this, in this example, a structure of the antireflection coating 2 is reconstructed to reduce the refractive index n₁ of the antireflection coating 2, so that the refractive index is close to or equal to 1.23.

Specifically, still referring to FIG. 5A, the antireflection coating 2 is of a porous structure. The porous structure is a structure in which a large quantity of holes that have different shapes and that are randomly arranged exist in the antireflection coating 2, and the remaining part is made of an optical material. For example, FIG. 5B shows a structure of an antireflection coating 2 of a porous structure. It should be understood that a quantity, shapes, locations, arrangements, and the like of holes in FIG. 5B should not be understood as a special limitation on a form of the antireflection coating 2. It should be understood that, there are a large quantity of hollow holes in the porous structure, and a medium in the hole is air. Therefore, the antireflection coating 2 as a whole may be considered as a structure formed by mixing air with a material forming antireflection coating 2. It should be noted that, a refractive index of air is a medium with a minimum refractive index other than air, and a material with a smaller refractive index cannot be found. Therefore, compared with a single-layer antireflection coating of a non-porous structure, existence of air inevitably reduces the refractive index n₁ of the antireflection coating 2, that is, the refractive index n₁ of the antireflection coating 2 can be reduced by designing the porous structure. In addition, a proportion of air may be controlled by adjusting a quantity of holes, to control a reduction range of the refractive index n₁ of the antireflection coating 2.

In this example, the refractive index n₁ of the antireflection coating 2 may be adjusted by controlling the quantity of holes in the porous structure, so that the refractive index is less than that of magnesium fluoride (or aluminum fluoride) to be closer to 1.23. Therefore, in this example, the antireflection coating 2 is disposed as the porous structure, so that an antireflection effect of the antireflection coating 2 can be improved.

It should be noted that, after an antireflection effect of the antireflection coating 2 is improved, an antireflection effect of the antireflection coating 2 at each angle is improved. In other words, in this example, in addition to improving an antireflection effect on vertical light, an antireflection effect on oblique light can also be improved, so that a reflection phenomenon of oblique light can be effectively suppressed. It should be understood that, after oblique light generated in a daily use process of a screen of an electronic device is effectively suppressed, a light reflection phenomenon of the screen is weakened, so that a user can more clearly identify displayed content on a screen of a mobile phone, thereby greatly improving visual experience of the user. In addition, after oblique light in a bending region of a foldable electronic device is effectively suppressed, a reflection phenomenon in the bending region is weakened, so that an optical crease in the bending region is weakened or even disappears, thereby greatly improving visual experience of the user.

In addition, the refractive index n₁ of the antireflection coating 2 may be adjusted by controlling the quantity of holes in the porous structure. Therefore, when a material of the antireflection coating 2 is selected, some materials with a slightly large refractive index may be selected. For example, a material that can be selected may be silicon oxide (whose refractive index is 1.55), silicon dioxide (whose refractive index is approximately 1.46), magnesium fluoride (whose refractive index is 1.38), lanthanum fluoride (whose refractive index is 1.58), yttrium fluoride (whose refractive index is 1.55), barium fluoride (whose refractive index is 1.40), aluminum fluoride (whose refractive index is 1.35), or the like. It can be learned that, when the antireflection coating 2 is set to the porous structure, more types of materials of the antireflection coating 2 can be selected.

It should be noted that, based on the technical term (3), it can be learned that, when an optical thickness of the antireflection coating 2 is n₁*d=(2k+1)λ₀/4, and n₁=\sqrt{n₀*n₂}, two columns of reflected light on an upper surface (a surface close to the AF layer 3) of the antireflection coating 2 and a lower surface (a surface close to the cover 1) of the antireflection coating 2 are opposite in phase, have an optical path difference of (2k+1)λ₀/2, so that the antireflection coating 2 can perform zero reflection on light whose wavelength is λ₀, where n₁ is the refractive index of the antireflection coating 2, n₀ is the refractive index of the air, n₂ is the refractive index of the cover 1, λ₀ is a wavelength of light in the air, k is a natural number, and d is a geometric thickness of the antireflection coating 2.

In this embodiment of this application, λ₀ that meets the relational expression n₁*d=(2k+1)λ₀/4 is referred to as a center wavelength of the antireflection coating 2. It should be understood that, the antireflection coating 2 can implement zero reflection on only incident light whose wavelength is the center wavelength λ₀, and an antireflection effect on incident light of a non-center wavelength is poorer than that of the center wavelength. A reason lies in the following: When other incident light of a non-center wavelength (for example, λ₁) passes through the antireflection coating 2 whose optical thickness is n₁*d=(2k+1)λ₀/4, an optical path difference between two columns of reflected light on the upper surface and the lower surface of the antireflection coating 2 is no longer (2k+1)λ₁/2, and a zero reflection condition is no longer met. Therefore, the cover structure 03 shown in FIG. 5A is applicable to a scenario in which a working band is narrow. Based on this, in a specific implementation process, when visible light in a specific narrow band needs to be reflected, a wavelength with a moderate wavelength in the band may be selected as the center wavelength, and the geometric thickness of the antireflection coating 2 is set based on the equation n₁*d=(2k+1)λ₀/4, so that better antireflection can be performed on the visible light in the band.

For example, if antireflection needs to be performed on light in a band of 760 nm to 780 nm, 770 nm may be selected as a center wavelength λ₀ in an equation d=(2k+1)λ₀/4n₁. For example, the cover 1 is glass whose refractive index is n₂=1.5, the refractive index n₀ of the air is 1, k=1, and n₁=1.23. It can be learned that d=156 nm. In other words, antireflection in the band of 760 nm to 780 nm and zero reflection in the band 780 nm can be implemented by simply setting the geometric thickness d of the antireflection coating 2 to 156 nm.

It should be understood that, based on the equation n₁*d=(2k+1)λ₀/4, it can be learned that larger λ₀ indicates smaller n₁ and larger d. When the cover 1 is the glass whose refractive index is n₂=1.5, in an extreme case, the quantity of holes may be controlled to control the refractive index n₁ of the antireflection coating 2 to be 1˜1.5, so that minimum n₁ is 1. In addition, a wavelength range of visible light is 380 nm˜780 nm, so that maximum λ₀ is 780 nm. It can be learned that, when λ₀=780 nm and n₁=1, maximum d is obtained, which is 195 nm. Considering an error factor, a maximum value of d is 200 nm. Therefore, when antireflection needs to be performed on another wavelength, the geometric thickness of the antireflection coating 2 is less than the maximum value 200 nm.

In some embodiments of this application, density of a hole that is of the antireflection coating 2 and that is close to a light-emitting surface of the antireflection coating 2 is greater than density of a hole that is of the antireflection coating 2 and that is away from the light-emitting surface of the antireflection coating. Therefore, holes on an upper side (a side close to the light-emitting surface of the antireflection coating 2) of the antireflection coating 2 are denser, and holes on a lower side (the side close to the light-emitting surface of the antireflection coating 2) of the antireflection coating 2 are sparser.

It should be noted that, when the holes on the upper side (the side close to the light-emitting surface of the antireflection coating 2) of the antireflection coating 2 are denser, light transmitted upwards is more likely to encounter the holes and be reflected to go downstream, and downstream light is more likely to pass through a region between the holes to continue to go downstream in an original direction. Based on this, the porous structure can help most light go downstream, and present excessive light from going upstream, thereby improving an antireflection effect.

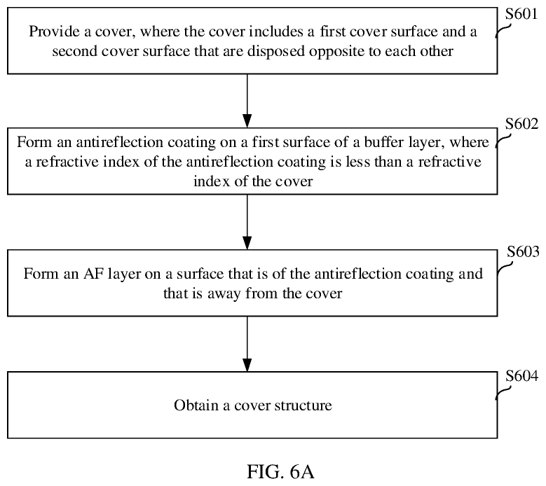

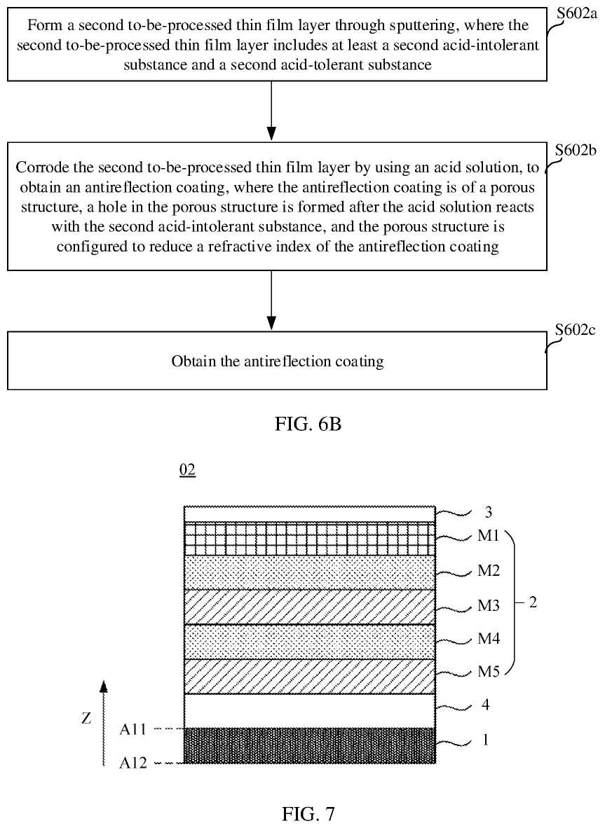

With reference to FIG. 5A and referring to FIG. 6A, to obtain the cover structure 02 in this example, FIG. 6A shows a method for manufacturing a cover structure according to an embodiment of this application. The method includes the following steps.

S601: Provide a cover, where the cover includes a first cover surface and a second cover surface that are disposed opposite to each other.

It should be understood that the cover 1 has two cover surfaces. Which one of the two cover surfaces is specifically the first cover surface A11 or the second cover surface A12 of the cover is not specifically limited in this embodiment of this application. The first cover surface A11 may be one of the two cover surfaces, and the second cover surface A12 may be the other one of the two cover surfaces.

S602: Form an antireflection coating on the first cover surface of the cover, where a refractive index of the antireflection coating is less than a refractive index of the cover.

Specifically, with reference to FIG. 5A and referring to FIG. 6B, a process of forming the antireflection coating 2 includes the following steps S602a to S602c.

S602a: Form a second to-be-processed thin film layer through sputtering, where the second to-be-processed thin film layer includes at least a second acid-intolerant substance and a second acid-tolerant substance.

It should be noted that, the second acid-intolerant substance is a substance that can react with an acid solution, and the second acid-tolerant substance is a substance that cannot react with the acid solution. Based on this, after the second to-be-processed thin film layer is corroded by using the acid solution, the second acid-tolerant substance is retained, and a large quantity of holes are formed after the second acid-intolerant substance is removed, so as to form the antireflection coating 2 of a porous structure. Based on this, the second acid-intolerant substance may be a metal oxide or the like, and the second acid-tolerant substance may be an available material of the antireflection coating 2, for example, silicon dioxide, lanthanum fluoride, yttrium fluoride, aluminum fluoride, or silicon oxide, but cannot be a substance such as the metal oxide that can react with the acid solution.

In a specific implementation process, an example in which the second acid-intolerant substance is the metal oxide is used. To form the second to-be-processed thin film layer, in some embodiments, first, a mixed target material of the metal oxide and the second acid-tolerant substance may be prepared. Then, ion beam sputtering is performed by using the mixed target material, and the mixed target material is deposited on the first cover surface A11 of the cover 1 after the sputtering, to form the second to-be-processed thin film layer. In some other embodiments, first, a mixed target material of a metal corresponding to the metal oxide and the second acid-tolerant substance may be prepared. Then, ion beam sputtering is performed by using the mixed target material, and after the sputtering, the mixed target material reacts with oxygen and is deposited on a surface that is of a buffer layer and that is away from the cover 1, to form the second to-be-processed thin film layer. It should be understood that a content of the metal or the metal oxide in the mixed target material may be controlled to control a content of the second acid-intolerant substance at the formed second to-be-processed thin film layer. A larger content of the second acid-intolerant substance indicates a larger quantity of holes retained after the second acid-intolerant substance reacts with the acid solution, and a larger quantity of holes in the formed antireflection coating 2, so that the refractive index m of the antireflection coating 2 is naturally smaller.

In this step, because the second to-be-processed thin film layer is formed by using a sputtering process, a basic unit forming the second to-be-processed thin film layer is a molecular-level substance or even an ion-level substance. Therefore, denser and more uniform holes can be formed after the second acid-intolerant substance reacts with the acid solution, so that surface roughness of the formed antireflection coating 2 is small, thereby improving wear-resistance performance of the antireflection coating 2. It should be understood that, when the cover structure 02 is applied to a screen surface of an electronic device such as a mobile phone, a user performs sliding on the cover structure 02 for a long time, and a structure of an antireflection coating 2 with poor wear-resistance performance is changed in a process of performing sliding by the user. Consequently, an antireflection effect of the antireflection coating is greatly reduced. On the contrary, in this embodiment, because the antireflection coating 2 has high wear-resistance performance, a structure of the antireflection coating is not easily changed in the process of performing sliding by the user, which helps ensure an antireflection effect of the antireflection coating, thereby improving reliability of the electronic device.

S602b: Corrode the second to-be-processed thin film layer by using an acid solution, to obtain an antireflection coating, where the antireflection coating is of a porous structure, a hole in the porous structure is formed after the acid solution reacts with the second acid-intolerant substance, and the porous structure is configured to reduce a refractive index of the antireflection coating.

In this example, the antireflection coating 2 of the porous structure is obtained through corrosion. Therefore, a quantity of holes in the antireflection coating 2 gradually decreases from an outer side (a side away from the cover 1) to an inner side (a side close to the cover 1), and fewer holes on the inner side lead to higher binding force between the porous structure and the buffer layer 4.

It should be noted that, considering that a part of the second acid-intolerant substance cannot be completely corroded when the second to-be-processed thin film layer is corroded by using the acid solution, based on this, to avoid a case in which the refractive index of the antireflection coating 2 is excessively high due to the remaining second acid-intolerant substance, some oxides with a low refractive index, for example, aluminum oxide (whose refractive index is 1.63), may be selected as second acid-intolerant substances. It should be further understood that, in addition to the selected second acid-tolerant substance, the antireflection coating 2 may further include some fully dissolved second acid-tolerant substances. In addition, to avoid corrosion of the cover 1, some weak acid solutions for example, a weakly acidic phosphoric acid, or a weakly acidic hydrochloric acid, may be selected as acid solutions.

S602c: Obtain the antireflection coating.

S603: Form an AF layer on a surface that is of the antireflection coating and that is away from the cover.

It should be understood that, in another embodiment, when the cover structure 02 does not include the AF layer 3, this step may not be included, that is, S604 is directly performed after S603.

S604: Obtain a cover structure.

### Example 2

As shown in FIG. 7, the cover structure 02 may include a cover 1 and an antireflection coating 2 that are sequentially stacked in a Z direction. For specific implementation of the cover 1 and the AF layer 3, refer to related content in Example 1. Details are not described herein again. Based on analysis in Example 1 that, it can be learned that the antireflection coating 2 of a single-layer structure is applicable to a scenario in which a working band is narrow. Based on this, an antireflection coating 2 that can perform antireflection in a wide band is provided in this example.

Specifically, the antireflection coating 2 may include a thin film layer M2 (that is, a second thin film layer), a thin film layer M3 (that is, a third thin film layer), a thin film layer M4 (that is, a fourth thin film layer), and a thin film layer M5 (that is, a fifth thin film layer). The thin film layer M5, the thin film layer M4, the thin film layer M3, and the thin film layer M2 are sequentially stacked in the Z direction, and the thin film layer M2 is further away from the cover 1. In addition, the thin film layer M2 (that is, the second thin film layer) is a low refraction layer, the thin film layer M3 (that is, the third thin film layer) is a high refraction layer, the thin film layer M4 is a low refraction layer, and the thin film layer M5 is a high refraction layer. In other words, the antireflection coating 2 includes four thin film layers whose refractive indexes are arranged by alternating between a higher rank and a lower rank, a thin film layer close to the cover 1 is a high refraction layer, and a thin film layer away from the cover 1 is a low refraction layer.

Among common optical thin film materials on the market, materials with a high refractive index include titanium oxide (whose refractive index is approximately 2.35), niobium oxide (whose refractive index is approximately 2.30), silicon nitride (whose refractive index is approximately 2.1), zirconium oxide (whose refractive index is approximately 2.05), and the like. Materials with a low refractive index include aluminum oxide (whose refractive index is approximately 1.55), silicon oxide (whose refractive index is approximately 1.55), silicon dioxide (whose refractive index is approximately 1.46), magnesium fluoride (whose refractive index is 1.38), lanthanum fluoride (whose refractive index is 1.58), yttrium fluoride (whose refractive index is 1.55), barium fluoride (whose refractive index is 1.40), aluminum fluoride (whose refractive index is 1.35), and the like. Based on this, in some embodiments, a material of the high refraction layer may be titanium oxide, niobium oxide, silicon nitride, zirconium oxide, or the like, and a material of the low refraction layer may be aluminum oxide, silicon oxide, silicon dioxide, magnesium fluoride, lanthanum fluoride, aluminum fluoride, yttrium fluoride, barium fluoride, or the like.

It can be learned that FIG. 7 shows a case in which the antireflection coating 2 includes four thin film layers whose refractive indexes are arranged by alternating between a higher rank and a lower rank. For ease of description, a group of a high refraction layer and a low refraction layer that are stacked in the Z direction are referred to as an antireflection unit. In this case, the example shown in FIG. 7 shows a case in which the antireflection coating 2 includes two antireflection units. Specifically, the thin film layer M3 and the thin film layer M2 that are sequentially stacked in the Z direction form one antireflection unit, and the thin film layer M5 and the thin film layer M4 that are sequentially stacked in the Z direction form one antireflection unit (that is, a second antireflection unit). This example is applicable to a scenario in which a working band is wide, that is, antireflection can be performed in all of the wide band. It should be understood that, in some scenarios in which a low requirement is imposed on a working band, the antireflection coating 2 may further include only one antireflection unit, that is, two thin film layers whose refractive indexes are arranged in descending order. In some scenarios in which a higher requirement is imposed on a working band, the antireflection coating 2 may further include more antireflection units that are sequentially stacked in the Z direction, that is, more even-numbered thin film layers whose refractive indexes are arranged by alternating between a higher rank and a lower rank, for example, six layers, eight layers, or ten layers, which are not described one by one in detail in this embodiment of this application. It should be understood that, a larger quantity of antireflection units indicates a larger quantity of layers, and a larger quantity of wavelengths that can be effectively suppressed by the antireflection coating 2, so that a stronger antireflection effect is naturally achieved.

It should be noted that, when vertical light is incident from a medium A with a refractive index n_{A} to a medium B with a refractive index n_{B}, a reflectivity R of the light on a boundary surface between the medium A and the medium B is:

$$R = \frac{{( {n}_{A} - {n}_{B} )}^{2}}{{( {n}_{A} + {n}_{B} )}^{2}}$$

It can be learned from the reflectivity formula that, a smaller difference between n_{A} and n_{B} indicates a lower reflectivity R on the boundary surface between the medium A and the medium B. It should be understood that, when light is directly incident from air to an upper surface (a surface away from the thin film layer M3) of the thin film layer M2, a reflectivity on the upper surface of the thin film layer M2 is positively related to a difference between a refractive index of the air and the thin film layer M2. To reduce the reflectivity on the upper surface of the thin film layer M2, the difference may be reduced. Because the refractive index of the air cannot be controlled, in this example, the refractive index of the thin film layer M2 is used to reduce the difference, so as to reduce the reflectivity on the surface of the thin film layer M2, thereby improving an antireflection effect of the antireflection coating 2.

Because the thin film layer M2 is a low refraction layer, a material of the thin film layer M2 is selected from some materials with a low refractive index. Therefore, the refractive index of the thin film layer M2 cannot be reduced simply by using a material to reduce the difference. Based on this, in this embodiment, a thin film layer M1 (that is, a first thin film layer) of a porous structure is plated on the upper surface (the surface away from the thin film layer M3) of the thin film layer M2. For a structure of the thin film layer M1 of the porous structure, refer to the structure shown in FIG. 5B. Details are not described herein again.

Based on related analysis in Example 1, it can be learned that a refractive index of the thin film layer M1 may be adjusted by controlling a quantity of porous structures of the thin film layer M1, so that the refractive index of the thin film layer M1 is less than the refractive index of the thin film layer M2. Therefore, in this example, equivalently, a thin film layer with a lower refractive index is plated on the surface of the thin film layer M2. The thin film layer M2 and the thin film layer M1 are considered as a whole. Compared with the single thin film layer M2, the thin film layer M2 and the thin film layer M1 as a whole have a lower overall refractive index. In this way, in this example, the thin film layer M1 and the thin film layer M2 are multiplexed as a low refraction layer of an antireflection unit, that is, the thin film layer M3, the thin film layer M2, and the thin film layer M1 that are stacked in the Z direction are used as an antireflection unit (that is, a first antireflection unit), so that a refractive index of the low refraction layer is naturally less than a refractive index obtained by using only the thin film layer M2 as the low refraction layer of the antireflection unit.

It should be understood that the first antireflection unit is an antireflection unit farthest away from the cover 1. Therefore, the low refraction layer that is of the first antireflection unit and that is formed by the thin film layer M2 and the thin film layer M1 is a new surface thin film layer of the antireflection coating 2. In this example, the quantity of porous structures of the thin film layer M1 may be controlled, so that the refractive index of the new surface thin film layer is as close as possible to a square root of the refractive index of the air and a refractive index of the thin film layer M3, so as to meet a zero reflection condition as far as possible. For specific analysis, refer to related content of the antireflection coating 2 in Example 1. Details are not described herein again. It should be understood that, when the antireflection coating 2 approaches the zero reflection condition, antireflection effects of the antireflection coating 2 at different angles may be improved. For specific analysis, refer to related description of the thin film layer M1 in Example 1. Details are not described herein again.

In addition, due to existence of the thin film layer M1 of the porous structure, most of light can be refracted into the lower thin film layer M2, and only a small part of the light is reflected. In addition, the part of reflected light is reflected for the second time on a hole wall in the porous structure, to be further antireflected. For specific analysis, refer to related content in Example 1. Details are not described herein again.

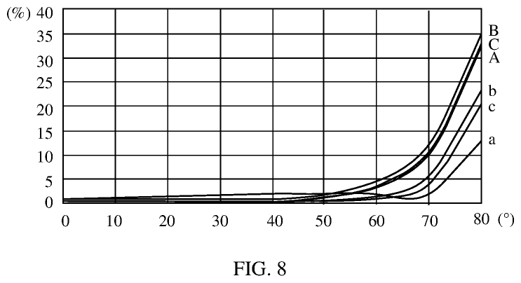

FIG. 8 is a diagram of comparison between reflectivities, for incident light, of antireflection coatings having thin film layers of different structures. A horizontal coordinate is an incident angle of incident light, and a vertical coordinate is a reflectivity. A curve A, a curve B, and a curve C respectively correspond to a reflectivity of a thin film layer that has an optical wavelength of 450 nm and that has a non-porous structure, a reflectivity of a thin film layer that has an optical wavelength of 550 nm and that has a non-porous structure, and a reflectivity of a thin film layer that has an optical wavelength of 650 nm and that as a non-porous structure. A curve a, a curve b, and a curve c respectively correspond to a reflectivity of a thin film layer that has an optical wavelength of 450 nm and that has a porous structure, a reflectivity of a thin film layer that has an optical wavelength of 550 nm and that has a porous structure, and a reflectivity of a thin film layer that has an optical wavelength of 650 nm and that has a porous structure.

It can be found through comparison that, regardless of whether the thin film layers have a hole, when incident light whose incident angle is below 60° is incident onto surfaces of the thin film layers, antireflection effects of antireflection coatings are equivalent. When large-angle oblique light whose incident angle is above 60° is incident onto the surfaces of the thin film layers, it is obvious that a reflectivity of an antireflection coating corresponding to the thin film layer of the porous structure is significantly less than that of an antireflection coating corresponding to the thin film layer of the non-porous structure. In other words, existence of the thin film layer of the porous structure can improve an antireflection effect of the antireflection coating on large-angle oblique light.

It should be noted that, in this example, the thin film layer M1 and the thin film layer M2 are multiplexed as a new surface thin film layer. It can be learned based on the technical term (3) that, when an optical thickness of the new surface thin film layer is n₁*d₁+n₂*d₂=(2k+1)λ₀/4, and a refractive index of the new surface thin film layer is equal to \sqrt{n₀*n₃}, two columns of reflected light on an upper surface (that is, a surface that is of the thin film layer M1 and that is away from the thin film layer M2) and a lower surface (that is, a surface that is of the thin film layer M2 and that is away from the thin film layer M1) of the surface thin film layer are opposite in phase, have an optical path difference of (2k+1)λ₀/2, and have a same amplitude, so that zero reflection can be performed on light whose wavelength is λ₀, where n₀ is a refractive index of air, n₂ is a refractive index of the thin film layer M2, n₁ is a refractive index of the thin film layer M1, λ₀ is a wavelength of light in the air, k is a natural number, d₁ is a geometric thickness of the thin film layer M1, and d₂ is a geometric thickness of the thin film layer M2.

In this embodiment of this application, λ₀ that meets the relational expression n₁*d₁+n₂*d₂=(2k+1)λ₀/4 is referred to as a center wavelength. It can be learned that the new surface thin film layer can implement zero reflection on the center wavelength λ₀, and can further perform antireflection on a wavelength other than the center wavelength λ₀ in cooperation with the thin film layer M3 to the thin film layer M5. Based on this, when visible light in a specific wide band needs to be reflected, a wavelength with a moderate wavelength in the band may be selected as the center wavelength λ₀, and a geometric thickness of the new surface thin film layer is set based on the equation, to cooperate with the thin film layer M3 to the thin film layer M5 to perform better antireflection in the band whose center wavelength is λ₀. It should be noted that, regardless of a specific center wavelength λ₀ that requires antireflection, a maximum value of a thin film of the new surface thin film layer is 200 nm. For specific analysis, refer to related content in Example 1. Details are not described herein again.

In some embodiments of this application, density of a hole that is of the thin film layer M1 and that is close to a light-emitting surface of the antireflection coating 2 is greater than density of a hole that is of the of the thin film layer M1 and that is away from the light-emitting surface of the antireflection coating 2. In this way, in this example, holes on an upper side (a side close to the light-emitting surface of the antireflection coating 2) of the thin film layer M1 are denser, and holes on a lower side (the side close to the light-emitting surface of the antireflection coating 2) of the thin film layer M1 are sparser.

When large-angle oblique light is incident onto the antireflection coating 3 and encounters a hole at the thin film layer M1, the oblique light is reflected or refracted on a hole wall, and then is reflected or refracted again when encountering another hole, until some light is transmitted from the light-emitting surface (upstream) of the antireflection coating 2, and some light is transmitted to the lower thin film layer M2 (downstream). It can be learned that light entering the thin film layer M1 is usually refracted and reflected a plurality of times, and then goes upstream or downstream. It should be understood that, after light is reflected a plurality of times, a reflectivity of the light is reduced (the reflectivity is less than 1%). Therefore, a reflectivity of light that is transmitted from the antireflection coating 3 due to the porous structure can be ignored. In addition, there is only an extremely small amount of upstream light, and most light goes downstream. A reason lies in the following: The holes on the upper side of the thin film layer M1 are denser, so that the upstream light is more likely to encounter the holes and be reflected to go downstream. However, the downstream light is more likely to pass through a region between the holes to continue to go downstream in an original direction. Based on this, because an amount of upstream light caused by the porous structure is extremely small, it is further verified that the reflectivity of the light that is transmitted from the antireflection coating 2 due to the porous structure can be ignored.

In addition, an incident angle (relative to the thin film layer M2) of the downstream light becomes smaller. A reason lies in the following: If the downstream light is large-angle oblique light, in a downstream process, the downstream light is easily reflected or refracted by the hole to change a transmission direction or even go upstream, instead of passing through the region between the holes to continue to go downstream in the original direction. Because the porous structure finally enables most light to go downstream, if the large-angle light needs to go downstream, an incident angle of the light is inevitably integrated by the holes in the porous structure in a refraction and reflection process, until the incident angle of the light is small and the light can be irradiated to the thin film layer M2. When the incident angle of the downstream light decreases, an optical path length n₂*d₂/cos θ through which the downlink light passes at the thin film layer M2 decreases, where d₂ is a geometric thickness of the second thin film layer, n₂ is the refractive index of the second thin film layer, λ₀ is a wavelength of light in the air, θ is an angle of incident light relative to the thin film layer M2, and k is a natural number. Therefore, the optical thickness of the surface thin film layer is closer to (2k+1)λ₀/4, to help improve an antireflection effect of the antireflection coating.

It should be understood that, in this example, based on an antireflection unit with an antireflection effect, the thin film layer M1 with a large-angle antireflection effect is further added to the cover structure 02. After the thin film layer M1 is worn, the remaining antireflection unit with an antireflection effect can continue to work. However, in Example 1, after the antireflection coating 2 is worn, the antireflection effect disappears. Obviously, this example is more reliable in terms of antireflection than Example 1.

In some embodiments of this application, the cover structure 02 may further include a buffer layer 4, and the buffer layer 4 is made of a high-surface-energy material. Generally, the high-surface-energy material is a material with contact angles of less than 120° with pure water. For example, a material of the buffer layer 2 may be silicon oxide, aluminum oxide, or the like. The buffer layer 4 includes a first surface and a second surface that are disposed opposite to each other. The antireflection coating 2 is stacked on the buffer layer 4. The antireflection coating 2 includes a first surface and a second surface that are disposed opposite to each other. The first surface of the antireflection coating 2 is a surface away from the cover 1, and the second surface of the antireflection coating 2 is a surface close to the cover 1. The first surface of the buffer layer 4 is in contact with the second surface of the antireflection coating 2, and the second surface of the buffer layer 4 is in contact with a cover surface of the cover 1. It should be understood that, in this example, a surface that is of the thin film layer M1 and that is away from the thin film layer M2 is the first surface of the antireflection coating 2, and a surface that is of the thin film layer M5 and that is in contact with the cover 1 is the second surface of the antireflection coating 2. It should be understood that, in another embodiment, the buffer layer 4 may not be disposed. This is not specifically limited in this embodiment of this application.

In this example, the buffer layer with high surface energy is processed between a hardening layer (the cover 1) and the antireflection coating 2, so that bonding force between the antireflection coating 2 and the cover 1 can be enhanced, and the cover structure 02 has better wear-resistance performance.

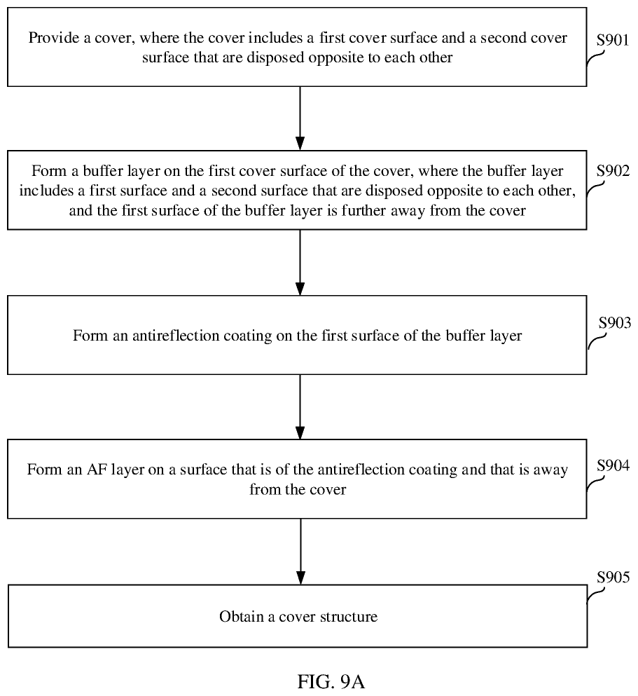

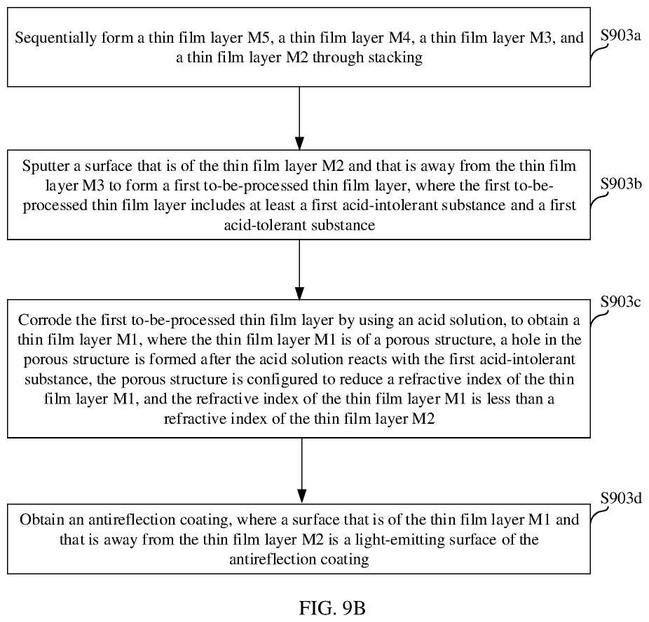

With reference to FIG. 7 and referring to FIG. 9A, to obtain the cover structure 02 in this example, FIG. 9A shows a method for manufacturing a cover structure according to an embodiment of this application. The method includes the following steps.

S901: Provide a cover, where the cover includes a first cover surface and a first cover surface that are disposed opposite to each other.

It should be understood that the cover 1 has two cover surfaces. Which one of the two cover surfaces is specifically the first cover surface A11 or the second cover surface A12 of the cover is not specifically limited in this embodiment of this application. The first cover surface A11 may be one of the two cover surfaces, and the second cover surface A12 may be the other one of the two cover surfaces.

S902: Form a buffer layer on the first cover surface of the cover, where the buffer layer includes a first surface and a second surface that are disposed opposite to each other, and the first surface of the buffer layer is further away from the cover.

It should be understood that, in another embodiment, when the cover structure 02 does not include the buffer layer 4, this step may not be included, that is, S903 is directly performed after S901.

S903: Form an antireflection coating on the first surface of the buffer layer.

It should be understood that, when the cover structure 02 does not include the buffer layer 4, this step may be replaced with forming the antireflection coating 2 on the first cover surface A11 of the cover 1.

Specifically, with reference to FIG. 7 and referring to FIG. 9B, a process of forming the antireflection coating 2 includes the following steps S903a to S903d.

S903a: Sequentially form a thin film layer M5, a thin film layer M4, a thin film layer M3, and a thin film layer M2 through stacking.

The thin film layer M5 is a high refraction layer, the thin film layer M4 is a low refraction layer, the thin film layer M3 is a high refraction layer, and the thin film layer M2 is a low refraction layer. For specific material selection of the high refraction layer and the low refraction layer, refer to related content of the cover structure 02 shown in FIG. 5A. Details are not described herein again.

S903b: Sputter a surface that is of the thin film layer M2 and that is away from the thin film layer M3 to form a first to-be-processed thin film layer, where the first to-be-processed thin film layer includes at least a first acid-intolerant substance and a first acid-tolerant substance.

Specific implementation and an implementation effect of this step are similar to those of S602a. For details, refer to related content in S602a. Details are not described herein again.

S903c: Corrode the first to-be-processed thin film layer by using an acid solution, to obtain a thin film layer M1, where the thin film layer M1 is of a porous structure, a hole in the porous structure is formed after the acid solution reacts with the first acid-intolerant substance, the porous structure is configured to reduce a refractive index of the thin film layer M1, and the refractive index of the thin film layer M1 is less than a refractive index of the thin film layer M2. For specific implementation and an implementation effect of this step, refer to related content in S602b. Details are not described herein again.

S903d: Obtain an antireflection coating, where a surface that is of the thin film layer M1 and that is away from the thin film layer M2 is a light-emitting surface of the antireflection coating.

It should be noted that, when the cover structure 02 does not include the buffer layer 4, this step may be replaced with sequentially forming the thin film layer M5, the thin film layer M4, the thin film layer M3, and the thin film layer M2 on the first cover surface A11 of the cover 1.

S904: Form an AF layer on a surface that is of the antireflection coating and that is away from the cover.

It should be understood that, in another embodiment, when the cover structure 02 does not include the AF layer 3, this step may not be included, that is, S905 is directly performed after S903.

S905: Obtain a cover structure.

### Example 3

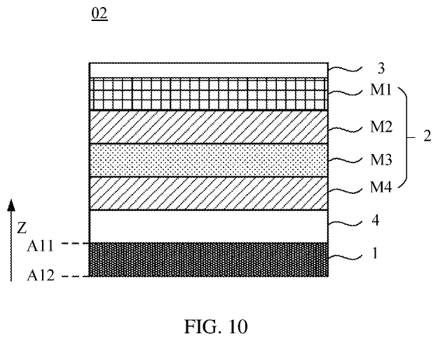

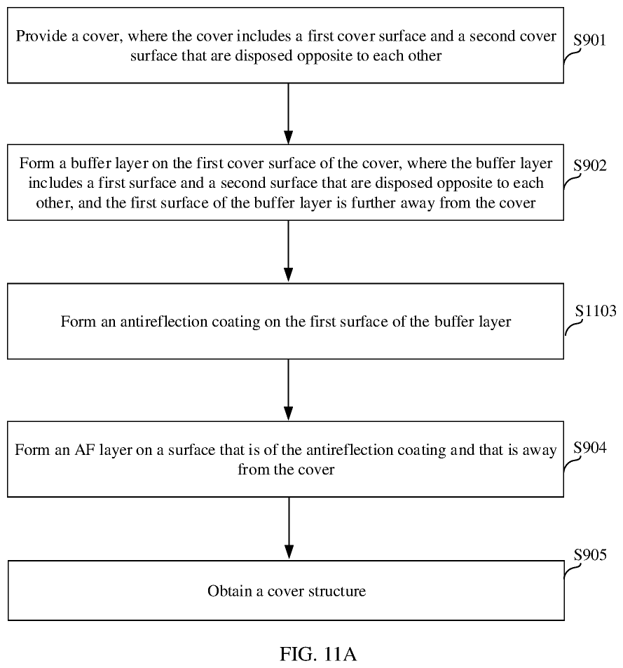

As shown in FIG. 10, the cover structure 02 may include a cover 1 and an antireflection coating 2. For specific implementation of the cover 1 and the AF layer 3, refer to related content in Example 1. Details are not described herein again.

In this example, the antireflection coating 2 may include a thin film layer M1 (that is, a first thin film layer), a thin film layer M2 (that is, a second thin film layer), a thin film layer M3 (that is, a third thin film layer), and a thin film layer M4 (that is, a fourth thin film layer). The thin film layer M4, the thin film layer M3, the thin film layer M2, and the thin film layer M1 are sequentially stacked in the Z direction, and the thin film layer M1 is further away from the cover 1. The thin film layer M1 is a low refraction layer, the thin film layer M2 is a high refraction layer, the thin film layer M3 is a low refraction layer, and the thin film layer M4 is a high refraction layer. In some embodiments, a material of the high refraction layer may be titanium oxide, niobium oxide, silicon nitride, zirconium oxide, or the like, and a material of the low refraction layer may be silicon oxide, silicon dioxide, magnesium fluoride, or the like.

It can be learned that as in Example 2, the antireflection coating 2 includes two antireflection units in this example. Specifically, the thin film layer M4 and the thin film layer M3 that are sequentially stacked in the Z direction form an antireflection unit (that is, a second antireflection unit); and the thin film layer M2 and the thin film layer M1 that are sequentially stacked in the Z direction form an antireflection unit (that is, a first antireflection unit). This example is applicable to a scenario in which a working band is wide, that is, antireflection can be performed in all wide bands. Unlike in Example 2, in this example, a thin film layer of a porous structure is no longer separately plated an upper part of the antireflection unit formed by the thin film layer M2 and the thin film layer M1 to reduce a difference between refractive indexes of air and the thin film layer M1. Instead, a surface thin film layer—the thin film layer M1 is directly disposed as a porous structure in this example. For a structure of the thin film layer M1 of the porous structure, refer to the structure shown in FIG. 5B. Details are not described herein again.

In this example, a quantity of porous structures of the thin film layer M1 may be controlled to reduce the refractive index of the thin film layer M1, and reduce a difference between the refractive index of the thin film layer M1 and the refractive index of the air, thereby reducing a reflectivity on a surface of the thin film layer M1, and improving an antireflection effect of the antireflection coating 2. In addition, the refractive index of the thin film layer M1 should be as close as possible to a square root of the refractive index of the air and a refractive index of the thin film layer M2, to meet a zero reflection condition as far as possible. For specific analysis, refer to related content of the thin film layer M1 in Example 1. Details are not described herein again.

In addition, due to existence of the thin film layer M1 of the porous structure, most of light can be refracted into the lower thin film layer M2, and only a small part of the light is reflected. In addition, the part of reflected light is reflected for the second time on a hole wall in the porous structure, to be further antireflected. For specific analysis, refer to related content in Example 1. Details are not described herein again.

It should be noted that, based on the technical term (3), it can be learned that, when an optical thickness of the surface thin film layer—the thin film layer M1 is n₁*d=(2k+1)λ₀/4, and n₁=\sqrt{n₀*n₂}, two columns of reflected light on an upper surface (a surface close to the AF layer 3) and the lower surface (a surface close to the cover 1) of the antireflection coating 2 are opposite in phase, have an optical path difference of (2k+1)λ₀/2, and have a same amplitude, so that the antireflection coating 2 can perform zero reflection on light whose wavelength is λ₀, where n₂ is the refractive index of the thin film layer M2, n₁ is the refractive index of the thin film layer M1, n₀ is the refractive index of the thin film layer M1, λ₀ is a wavelength of light in the air, k is a natural number, and d₂ is a geometric thickness of the thin film layer M2. In this embodiment of this application, λ₀ that meets the relational expression n₁*d=(2k+1)λ₀/4 is referred to as a center wavelength. It can be learned that the thin film layer M1 can implement zero reflection on the center wavelength λ₀, and can further perform antireflection on a wavelength other than the center wavelength λ₀ in cooperation with the thin film layer M2 to the thin film layer M4. Based on this, when visible light in s specific wide band needs to be reflected, a wavelength with a moderate wavelength in the band may be selected as the center wavelength λ₀, and a geometric thickness of the thin film layer M1 is set based on the equation n₁*d=(2k+1)λ₀/4, to cooperate with the thin film layer M2 to the thin film layer M4 to perform better antireflection in the band whose center wavelength is λ₀. It should be noted that, regardless of a specific center wavelength λ₀ that requires antireflection, a maximum value of a thin film of the new surface thin film layer is 200 nm. For specific analysis, refer to related content in Example 1. Details are not described herein again.

In some embodiments of this application, the cover structure 02 may further include a buffer layer 4, and surface energy of the buffer layer 4 is greater than a preset threshold. For setting of the buffer layer 4, refer to specific implementation and effects in Example 1. Details are not described herein again. It should be understood that, in this example, a surface that is of the thin film layer M1 and that is attached to the cover 1 is a first surface of the antireflection coating 2, and a surface that is of the thin film layer M4 and that is attached to the cover 1 is a second surface of the antireflection coating 2.

In some embodiments of this application, the cover structure 02 may further include a buffer layer 4, and surface energy of the buffer layer 4 is greater than a preset threshold. For setting of the buffer layer 4, refer to specific implementation and effects in Example 2. Details are not described herein again. It should be understood that, in this example, a surface that is of the thin film layer M1 and that is attached to the cover 1 is a first surface of the antireflection coating 2, and a surface that is of the thin film layer M2 and that is attached to the cover 1 is a second surface of the antireflection coating 2.

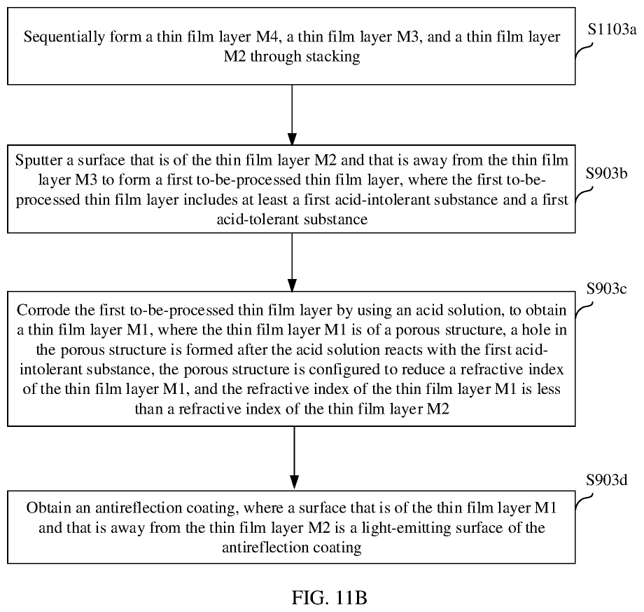

With reference to FIG. 10 and referring to FIG. 11A, to obtain the cover structure 02 in this example, FIG. 11A shows a method for manufacturing a cover structure according to an embodiment of this application.

It should be noted that, the method shown in FIG. 11A is similar to that shown in FIG. 9A, and a difference lies in a process of forming the antireflection coating 2 in S1103 shown in FIG. 11A. For details, refer to FIG. 11B. Different from S903a shown in FIG. 9B, S1103a shown in FIG. 11B is as follows.

S1103a: Sequentially form a thin film layer M4, a thin film layer M3, and a thin film layer M2 through stacking.

The thin film layer M4 is a high refraction layer, the thin film layer M3 is a low refraction layer, and the thin film layer M2 is a high refraction layer.

It should be noted that, other steps are similar to the steps of the methods shown in FIG. 9A and FIG. 9B. For implementation of the other steps, refer to related steps in FIG. 9A and FIG. 9B. Details are not described herein again.

The foregoing descriptions are merely specific implementations of embodiments of this application, but the protection scope of embodiments of this application is not limited thereto. Any variation or replacement within the technical scope disclosed in embodiments of this application shall fall within the protection scope of embodiments of this application. Therefore, the protection scope of embodiments of this application shall be subject to the protection scope of the claims.

1. An antireflection coating, wherein the antireflection coating comprises:
one or more antireflection units, wherein the plurality of antireflection units are sequentially stacked in a first direction, the first direction is a light-emitting direction of the antireflection coating, and the one or more antireflection units comprise a first antireflection unit, wherein
the first antireflection unit comprises a first thin film layer and a second thin film layer, the second thin film layer and the first thin film layer are sequentially stacked in the first direction, and a surface that is of the first thin film layer and that is away from the second thin film layer is a light-emitting surface of the antireflection coating; and
the first thin film layer is of a porous structure, the porous structure is configured to reduce a refractive index of the first thin film layer, and the refractive index of the first thin film layer is less than a refractive index of the second thin film layer.

2. The antireflection coating according to claim 1, wherein density of a hole that is of the first thin film layer and that is close to the light-emitting surface of the antireflection coating is greater than density of a hole that is of the first thin film layer and that is away from the light-emitting surface of the antireflection coating.

3. The antireflection coating according to claim 1, wherein a geometric thickness of the first thin film layer meets the following equation:
n₁*d₁(2k+1)λ₀/4
wherein d₁ is the geometric thickness of the first thin film layer, n₁ is the refractive index of the first thin film layer, λ₀ is a wavelength of light in the air, and k is a natural number.

4. The antireflection coating according to claim 3, wherein the plurality of antireflection units further comprise a second antireflection unit, and the second antireflection unit is stacked on a surface that is of the second thin film layer and that is away from the first thin film layer; and
the second antireflection unit comprises a third thin film layer and a fourth thin film layer, the fourth thin film layer and the third thin film layer are sequentially stacked in the first direction, a refractive index of the fourth thin film layer is greater than a refractive index of the third thin film layer, and the refractive index of the third thin film layer is less than the refractive index of the second thin film layer.

5. The antireflection coating according to claim 1, wherein the first antireflection unit further comprises a third thin film layer; and
the second thin film layer is stacked on a surface of the third thin film layer, and a refractive index of the third thin film layer is greater than the refractive index of the second thin film layer.

6. The antireflection coating according to claim 5, wherein a thickness of the first thin film layer meets the following equation:
n₁*d₁+n₂*d₂=(2k+1)λ₀/4
wherein d₁ is the geometric thickness of the first thin film layer, n₁ is the refractive index of the first thin film layer, d₂ is a geometric thickness of the second thin film layer, n₂ is the refractive index of the second thin film layer, λ₀ is a wavelength of light in the air, and k is a natural number.

7. The antireflection coating according to claim 6, wherein the plurality of antireflection units further comprise a second antireflection unit, and the second antireflection unit is stacked on a surface that is of the third thin film layer and that is away from the second thin film layer; and
the second antireflection unit comprises a fourth thin film layer and a fifth thin film layer, the fifth thin film layer and the fourth thin film layer are sequentially stacked in the first direction, a refractive index of the fifth thin film layer is greater than a refractive index of the fourth thin film layer, and the refractive index of the fourth thin film layer is less than the refractive index of the third thin film layer.

8. The antireflection coating according to claim 1, wherein a geometric thickness of the first thin film layer is 200 nm or less.

9. The antireflection coating according to claim 1, wherein the first thin film layer is made of a transparent material.

10. The antireflection coating according to claim 1, wherein the antireflection coating is applied to a foldable electronic device.

11. A cover structure, comprising:
a cover; and
the antireflection coating according to claim 1, wherein the antireflection coating and the cover are stacked, and a light-emitting surface of the antireflection coating is further away from the cover.

12. The cover structure according to claim 11, further comprising a buffer layer, wherein the buffer layer is made of a high-surface-energy material;
the buffer layer is stacked between the cover and the antireflection coating, and comprises a first surface and a second surface that are disposed opposite to each other; and
the first surface of the buffer layer is in contact with the antireflection coating, and the second surface of the buffer layer is in contact with a cover surface of the cover.

13. An antireflection coating, wherein the antireflection coating is of a porous structure, and the porous structure is configured to reduce a refractive index of the antireflection coating.

14. The antireflection coating according to claim 13, wherein density of a hole that is of the antireflection coating and that is close to a light-emitting surface of the antireflection coating is greater than density of a hole that is of the antireflection coating and that is away from the light-emitting surface of the antireflection coating.

15. The antireflection coating according to claim 13, wherein a geometric thickness of the antireflection coating meets the following equation:
n₁*d₁=(2k+1)λ₀/4
wherein d₁ is the geometric thickness of the antireflection coating, n₁ is the refractive index of the antireflection coating, λ₀ is a wavelength of light in the air, and k is a natural number.

16. The antireflection coating according to claim 13, wherein a geometric thickness of the antireflection coating is 200 nm or less.

17. The antireflection coating according to claim 13, wherein the antireflection coating is made of a transparent material.

18. The antireflection coating according to claim 13, wherein the antireflection coating is applied to a foldable electronic device.

19-20. (canceled)

21. A method for manufacturing an antireflection coating, comprising:
forming a second thin film layer;
sputtering a surface of the second thin film layer to form a first to-be-processed thin film layer, wherein the first to-be-processed thin film layer comprises at least a first acid-intolerant substance and a first acid-tolerant substance;
corroding the first to-be-processed thin film layer by using an acid solution, to form a first thin film layer of a porous structure, wherein a hole in the porous structure is formed after the acid solution reacts with the first acid-intolerant substance, the porous structure is configured to reduce a refractive index of the first thin film layer, and the refractive index of the first thin film layer is less than a refractive index of the second thin film layer; and
obtaining an antireflection coating, wherein a surface that is of the first thin film layer and that is away from the second thin film layer is a light-emitting surface of the antireflection coating.

22. (canceled)
